(19) United States
(12) Patent Application Publication
(10) Pub. No.: US 2009/0229759 A1
(43) Pub. Date: Sep. 17, 2009

(54) ANNULAR ASSEMBLY FOR PLASMA PROCESSING, PLASMA PROCESSING APPARATUS, AND OUTER ANNULAR MEMBER

(75) Inventors: Masahiro OGASAWARA, Nirasaki-shi (JP); Akihito Toda, Nirasaki-shi (JP); Hiroshi Tsuchiya, Hwaseong-si (KR); Shigeki Doba, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/399,375

(22) Filed: Mar. 6, 2009

Related U.S. Application Data
(60) Provisional application No. 61/050,764, filed on May 6, 2008.

(30) Foreign Application Priority Data
Mar. 13, 2008 (JP) 2008-064427

(51) Int. Cl. H01L 21/306

(52) U.S. Cl. 156/345.51

(57) ABSTRACT

An annular assembly for plasma processing which can prevent poor attraction of a substrate. The annular assembly is comprised of a focus ring that is mounted on a mounting stage and disposed such as to surround an outer periphery of a substrate subjected to the plasma processing, and an outer annular member that is disposed such as to surround an outer periphery of the focus ring. The outer annular member has an exposed surface that is exposed into a processing space in which plasma is produced, and the exposed surface is covered with yttria.

### BACKGROUND OF THE INVENTION

1. Field of the Invention

The present invention relates to an annular—assembly for plasma processing, a plasma processing apparatus, and an outer annular member, and in particular relates to an annular assembly for plasma processing, which is disposed such as to surround an outer periphery of a substrate that is mounted on a mounting stage and subjected to plasma processing.

2. Description of the Related Art

In general, a plasma processing apparatus that subjects a disk-shaped wafer as a substrate to plasma processing has a processing chamber in which a wafer is accommodated, a showerhead that supplies a process gas into the processing chamber, and a mounting stage that is disposed in the processing chamber and on which the wafer is mounted. The showerhead is connected to an upper radio frequency power source and acts as an upper electrode that applies radio frequency electrical power into the processing chamber. The mounting stage is connected to a lower radio frequency power source and acts as a lower electrode that applies radio frequency electrical power into the processing chamber. In the plasma processing apparatus, radio frequency electrical power is applied to a process gas supplied into the processing chamber, whereby the process gas is turned into plasma so as to produce ions and radicals. The wafer is subjected to the plasma processing by the ions and the radicals. Moreover, the mounting stage has in an upper portion thereof an electrostatic chuck that attracts and holds the wafer through a Coulomb force or a Johnsen-Rahbek force, and the electrostatic chuck is cooled so as to control the processing temperature of the wafer attracted to and held on a surface of the electrostatic chuck.

FIG. 5A is a cross-sectional view showing an electrostatic chuck and its vicinity in a conventional plasma processing apparatus.

Referring to FIG. 5A, around the electrostatic chuck 21, an annular focus ring 23 is disposed such as to surround a wafer W mounted on the electrostatic chuck 21, and an annular cover ring 50 is disposed such as to surround an outer periphery of the focus ring 23. The focus ring 23 is made of a conductive material such as silicon, and the cover ring 50 is made of an insulating material such as quartz. The focus ring 23 focuses plasma toward the wafer W, and the cover ring 50 protects a mounting stage 51 from plasma.

In the case that the focus ring 23 is disposed such that the level of the upper surface thereof is substantially the same as the level of a to-be-processed surface of the wafer W, the wafer W and the focus ring 23 are at substantially the same potential, and hence ions and radicals tend to enter a gap between the outer periphery of the wafer W and an inner periphery of the focus ring 23. In general, in the case that etching processing as plasma processing is carried out on a silicon oxide film (SiO₂ film) formed on the to-be-processed surface of the wafer W, CF-based gas is used as a process gas, and hence CFx radicals produced from the CF-based gas enter the gap between the outer periphery of the wafer W and the inner periphery of the focus ring 23. The CFx radicals reach an outer periphery of the electrostatic chuck 21 under the wafer W, and because the electrostatic chuck 21 is cooled as described above, the CFx radicals cause an attracting reaction on the outer periphery of the electrostatic chuck 21 and turn into CF type deposit D, which becomes attached to the outer periphery of the electrostatic chuck 21 (FIG. 5A).

Conventionally, to remove the above described deposit D or the like, the plasma processing apparatus carries out dry cleaning processing using oxygen gas after processed wafers W are transferred out (see, for example, Japanese Laid-open Patent Publication (Kokai) No. 2007-214512).

However, in the above described dry cleaning processing using oxygen gas, the CF type deposit i.e. deposit D containing fluorine resists being dissolved by oxygen radicals, and it is thus difficult to completely dissolve the deposit D. For this reason, even if the dry cleaning processing is carried out in the processing chamber at the time of mass production of wafers W during which the plasma processing is repeatedly carried out, the deposit D accumulates in the gap between the outer periphery of the electrostatic chuck 21 and the inner periphery of the focus ring 23, and the accumulated deposit D may project out from a surface of the electrostatic chuck 21 (FIG. 5B). At this time, the deposit D inhibits the wafer W from coming into contact with the surface of the electrostatic chuck 21, and the wafer W is brought to a state in which it floats above the surface of the electrostatic chuck 21.

When the wafer W is brought to a state in which it floats above the surface of the electrostatic chuck 21, helium gas as a heat transfer gas supplied into a gap between the wafer W and the electrostatic chuck 21 leaks from the gap. Upon detecting the leakage of the helium gas, the plasma processing apparatus recognizes the poor attraction of the wafer W and stops operating. Thus, to resume the operation of the plasma processing apparatus, maintenance for removing the above described deposit D is required, and hence there is the problem that the rate of operation of the plasma processing apparatus considerably decreases.

### SUMMARY OF THE INVENTION

The present invention provides an annular assembly for plasma processing, a plasma processing apparatus, and an outer annular member, which can prevent poor attraction of a substrate.

Accordingly, in a first aspect of the present invention, there is provided an annular assembly for plasma processing, comprising a focus ring that is mounted on a mounting stage and disposed such as to surround an outer periphery of a substrate subjected to plasma processing and an outer annular member that is disposed such as to surround an outer periphery of the focus ring, wherein the outer annular member comprises an exposed surface that is exposed into a plasma producing space in which plasma is produced, and the exposed surface is covered with yttria.

According to the first aspect of the present invention, the exposed surface of the outer annular member, which is exposed into a plasma producing space, is covered with yttria. In the case that CF-based gas is turned into plasma, and the substrate is subjected to plasma processing by the plasma, CFx radicals are produced in the plasma producing space. However, the yttria in the outer annular member pulls out fluorine in the CFx radicals, and hence radicals that enter a gap between the outer periphery of the substrate and an inner periphery of the focus ring and reach an outer periphery of the mounting stage hardly contains fluorine, and hence deposit arising from the radials is carbon-rich deposit. The carbon-rich deposit can be easily removed by dry cleaning processing using oxygen. As a result, if the dry cleaning processing is carried out at the time of mass production of substrates, no deposit accumulates in a gap between the outer periphery of the mounting stage and the inner periphery of the focus ring, and as a result, poor attraction of the substrates can be prevented.

The first aspect of the present invention can provide an annular assembly for plasma processing, comprising an inner annular member that is disposed such as to surround the outer periphery of the focus ring, and is closer to the focus ring than the outer annular member.

According to the first aspect of the present invention, the inner annular member is disposed such as to surround the outer periphery of the focus ring and closer to the focus ring than the outer annular member. That is, the focus ring and the inner annular member are interposed between the outer annular member and the substrate mounted on the mounting stage. As a result, the focus ring and the inner annular member can be caused to act as barriers that prevent yttria contamination resulting from dispersion of yttria in the outer annular member from spreading to the substrate, thus preventing the substrate from being contaminated with yttria.

The first aspect of the present invention can provide an annular assembly for plasma processing, wherein the inner annular member comprises quartz.

According to the first aspect of the present invention, the inner annular member is formed of quartz. Because quartz is plasma resistant, the mounting stage can be reliably protected from plasma.

The first aspect of the present invention can provide an annular assembly for plasma processing, wherein the inner annular member is disposed such that an upper surface thereof is at a lower level than an upper surface of the focus ring and at a higher level than an upper surface of the outer annular member.

According to the first aspect of the present invention, the inner annular member is disposed such that the upper surface thereof is at a lower level than the upper surface of the focus ring and at a higher level than the upper surface of the outer annular member. That is, the members constituting the annular assembly for plasma processing are disposed in the form of a ladder from the focus ring down to the outer annular member. As a result, the flow of a process gas flowing from above the focus ring to above the outer annular member in the plasma producing space and further to the side of the mounting stage can be smoothed, and hence the process gas can be smoothly discharged.

The first aspect of the present invention can provide an annular assembly for plasma processing, wherein the outer annular member comprises an upper surface thereof formed as an inclined surface that is inclined downward toward an outer periphery.

According to the first aspect of the present invention, the upper surface of the outer annular member is formed as an inclined surface that is inclined downward toward the outer periphery. As a result, the flow of a process gas supplied into the plasma producing space and discharged downward through the side of the mounting stage is never obstructed by upper surface of the outer annular member, and hence the process gas can be smoothly discharged.

Accordingly, in a second aspect of the resent invention, there is provided a plasma processing apparatus comprising a processing chamber in which a substrate is subjected to plasma processing, a mounting stage that is disposed in the processing chamber, and on which the substrate is mounted, and an annular assembly for plasma processing which is disposed such as to surround an outer periphery of the substrate mounted on the mounting stage, wherein the annular assembly for plasma processing comprises a focus ring that is disposed such as to surround the outer periphery of the substrate, and an outer annular member that is disposed such as to surround an outer periphery of the focus ring, and the outer annular member comprises an exposed surface that is exposed into a plasma producing space in which plasma is produced, and the exposed surface is covered with yttria.

Accordingly, in a third aspect of the present invention, there is provided an outer annular member that is disposed such as to surround an periphery of a focus ring that is disposed such as to surround an outer periphery of a substrate mounted on a mounting stage and subjected to plasma processing, comprising an exposed surface that is exposed into a plasma producing space in which plasma is produced, and the exposed surface is covered with yttria.

The features and advantages of the invention will become more apparent from the following detailed description taken in conjunction with the accompanying drawings.

### BRIEF DESCRIPTION OF THE DRAWINGS

FIG. 1 is a cross-sectional view schematically showing the construction of a plasma processing apparatus to which an annular assembly for plasma processing according to an embodiment of the present invention is applied;

FIG. 2 is an enlarged cross-sectional view showing the annular assembly for plasma processing in FIG. 1 and its vicinity;

FIGS. 3A and 3B are cross-sectional views schematically showing variations of the construction of the annular assembly for plasma processing in FIG. 1, in which FIG. 3A shows the case that the annular assembly for plasma processing is provided with only an outer cover ring in addition to a focus ring, and FIG. 3B shows the case that the outer cover ring is formed in a shape similar to the shape of a conventional cover ring in the construction shown in FIG. 3A;

FIGS. 4A, 4B, 4C, and 4D are graphs showing the results of etching processing on an oxide film and a photoresist film in an example 2 of the present invention and a comparative example 2, in which FIG. 4A is a graph showing the distribution of etch rates in the etching processing on the oxide film in the example 2, FIG. 4B is a graph showing the distribution of etch rates in the etching processing on the photoresist film in the example 2, FIG. 4C is a graph showing the distribution of etch rates in the etching processing on the oxide film in the comparative example 2, and FIG. 4D is a graph showing the distribution of etch rates in the etching processing on the photoresist film in the comparative example 2; and

FIGS. 5A and 5B are cross-sectional views showing an electrostatic chuck in a conventional plasma processing apparatus, in which FIG. 5A shows the case that CF type deposit becomes attached to an outer periphery of the electrostatic chuck, and FIG. 5B shows the case that CF type deposit projects out from a surface of the electrostatic chuck.

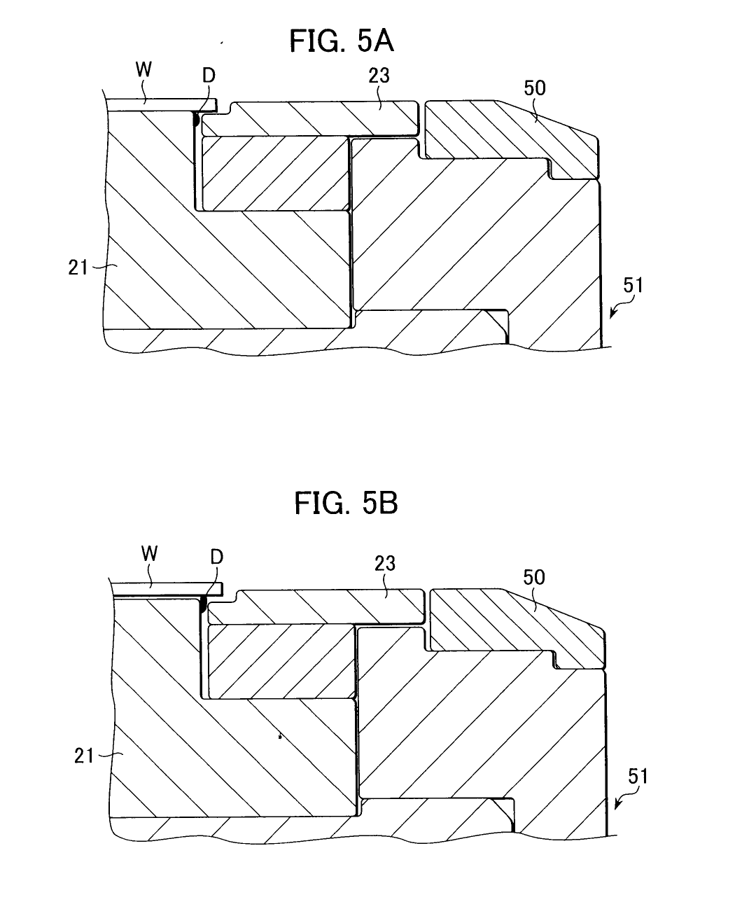

### DETAILED DESCRIPTION OF PREFERRED EMBODIMENTS

The present invention will now be described in detail with reference to the drawings showing a preferred embodiment thereof.

First, a description will be given of a plasma processing apparatus to which an annular assembly for plasma processing according to the present embodiment is applied.

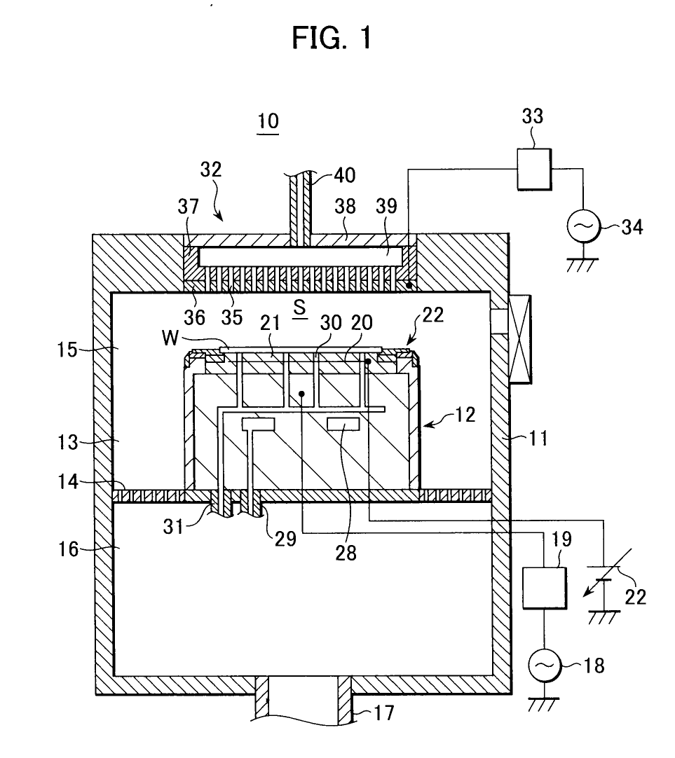

FIG. 1 is a cross-sectional view schematically showing the construction of a plasma processing apparatus to which an annular assembly for plasma processing according to the present embodiment is applied. The plasma processing apparatus is constructed such as to carry out etching processing on a silicon oxide film (SiO₂ film) formed on a semiconductor wafer as a substrate.

Referring to FIG. 1, the plasma processing apparatus 10 has a chamber 11 in which a semiconductor wafer (hereinafter referred to merely as a “wafer”) W having a diameter of, for example, 300 mm is accommodated, and a cylindrical susceptor 12 (mounting stage) on which the wafer W is mounted is disposed in the chamber 11. In the plasma processing apparatus 10, a side exhaust path 13 that acts as a flow path through which gas above the susceptor 12 is exhausted out of the chamber 11 is formed between an inner side wall of the chamber 11 and the side face of the susceptor 12. An exhaust plate 14 is disposed part way along the side exhaust path 13.

The exhaust plate 14 is a plate-shaped member having a large number of holes therein and acts as a partition plate that partitions the chamber 11 into an upper portion and a lower portion. Plasma is produced in a processing space S (plasma producing space) between the susceptor 12 and a showerhead 32, described later, in the upper portion (hereinafter referred to as the “reaction chamber”) 15 of the chamber 11 partitioned by the exhaust plate 14. An exhaust pipe 17 through which gas in the chamber 11 is exhausted is connected to the lower portion (hereinafter referred to as the “exhaust chamber (manifold)”) 16 of the chamber 11. The exhaust plate 14 captures or reflects ions and radicals produced in the processing space S of the reaction chamber 15 to prevent leakage of the ions and the radicals into the manifold 16.

The exhaust pipe 17 has a TMP (turbo-molecular pump) and a DP (dry pump) (both not shown) connected thereto, and these pumps reduce the pressure in the chamber 11 down to a vacuum state. Specifically, the DP reduces the pressure in the chamber 11 from atmospheric pressure down to an intermediate vacuum state (e.g. a pressure of not more than 1.3×10 Pa (0.1 Torr)), and the TMP is operated in collaboration with the DP to reduce the pressure in the chamber 11 down to a high vacuum state (e.g. a pressure of not more than 1.3×10⁻³ Pa (1.0×10⁻⁵ Torr)), which is at a lower pressure than the intermediate vacuum state. It should be noted that an APC valve (not shown) controls the pressure in the chamber 11.

A lower radio frequency power source 18 is connected to the susceptor 12 in the chamber 11 via a lower matcher 19. The lower radio frequency power source 18 supplies predetermined radio frequency electrical power to the susceptor 12. The susceptor 12 thus acts as a lower electrode. Moreover, the lower matcher 19 reduces reflection of the radio frequency electrical power from the susceptor 12 so as to maximize the efficiency of the supply of the radio frequency electrical power into the susceptor 12.

An electrostatic chuck 21 having an electrostatic electrode plate 20 therein is provided in an upper portion of the susceptor 12. The electrostatic chuck 21 is formed by placing an upper disk-shaped member, which has a smaller diameter than a lower disk-shaped member having a certain diameter, over the lower disk-shaped member. It should be noted that the electrostatic chuck 21 is made of ceramic. When a wafer W is mounted on the susceptor 12, the wafer W is disposed on the upper disk-shaped member of the electrostatic chuck 21.

A DC power source 22 is electrically connected to the electrostatic electrode plate 20 in the electrostatic chuck 21. Upon a positive DC voltage being applied to the electrostatic electrode plate 20, a negative potential is produced on a surface of the wafer W which faces the electrostatic chuck 21 (hereinafter referred to as “the rear surface of the wafer W”). A potential difference thus arises between the electrostatic electrode plate 20 and the rear surface of the wafer W, and hence the wafer W is attracted to and held on the upper disk-shaped member of the electrostatic chuck 21 through a Coulomb force or a Johnsen-Rahbek force due to the potential difference.

Moreover, an annular assembly for plasma processing (assembly) 22 is disposed on an upper portion of the susceptor 12 such as to surround an outer periphery of the wafer W mounted on the electrostatic chuck 21.

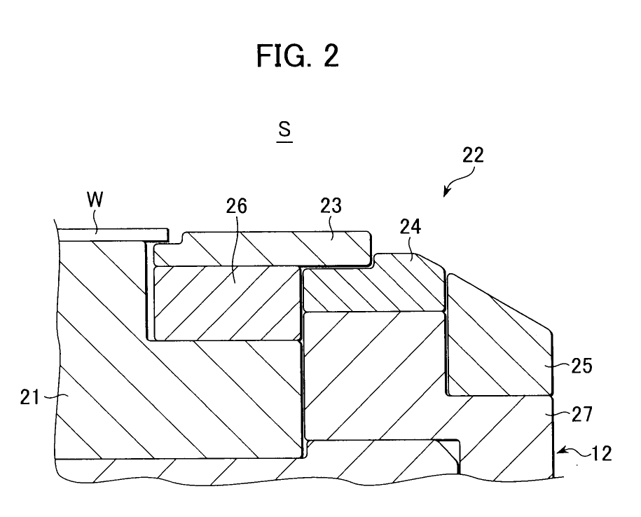

FIG. 2 is an enlarged cross-sectional view showing the annular assembly for plasma processing in FIG. 1 and its vicinity.

Referring to FIG. 2, the annular assembly for plasma processing 22 is comprised of an annular focus ring 23 that is disposed such as to surround the outer periphery of the wafer W mounted on the electrostatic chuck 21, an annular inner cover ring 24 (inner annular member) that is disposed such as to surround an outer periphery of the focus ring 23, and an annular outer cover ring 25 (outer annular member) that is disposed such as to surround an outer periphery of the inner cover ring 24. The inner cover ring 24 is disposed such that an upper surface thereof is at a lower level than an upper surface of the focus ring 23, and the outer cover ring 25 is disposed such that an upper surface thereof is at a lower level than the upper surface of the inner cover ring 24 and is formed as an inclined surface that is inclined downward toward the outer periphery. Moreover, the focus ring 23 is mounted on an annular ring spacer 26 mounted on the electrostatic chuck 21, and the inner cover ring 24 and the outer cover ring 25 are mounted on an annular susceptor cover member 27 that covers the side face of the susceptor 12. The focus ring 23 is made of a conductive material such as silicon (Si), and the inner cover ring 24 is made of an insulating material such as quartz (Qz) or the like, which is plasma resistant. The outer cover ring 25 is made of aluminum (Al), and an exposed surface of the outer cover ring 25 which is exposed into the processing space S is covered with yttria (Y₂O₃). The focus ring 23 focuses plasma produced in the processing space S toward a front surface of the wafer W, thus improving the efficiency of the etching processing. The inner cover ring 24 and the outer cover ring 25 protect the susceptor 12 from plasma.

Referring again to FIG. 1, an annular coolant chamber 28 that extends, for example, in a circumferential direction of the susceptor 12 is provided inside the susceptor 12. A coolant, for example, cooling water or a Galden (registered trademark) fluid, at a low temperature is circulated through the coolant chamber 28 via a coolant piping 29 from a chiller unit (not shown). The susceptor 12 cooled by the low-temperature coolant cools the wafer W and the focus ring 23 via the electrostatic chuck 21.

A plurality of heat transfer gas supply holes 30 are opened to a portion of the upper surface of the upper disk-shaped member of the electrostatic chuck 21 on which the wafer W is attracted and held (hereinafter referred to as the “attracting surface”). The heat transfer gas supply holes 30 are connected to a heat-transmitting gas supply unit (not shown) via a heat-transmitting gas supply line 31, and the heat-transmitting gas supply unit supplies helium (He) gas as a heat transfer gas into a gap between the attracting surface and the rear surface of the wafer W via the heat transfer gas supply holes 30. The helium gas supplied into the gap between the attracting surface and the rear surface of the wafer W effectively transfers heat from the wafer W to the electrostatic chuck 21.

The showerhead 32 is disposed in a ceiling portion of the chamber 11 such as to face the susceptor 12. An upper radio frequency power source 34 is connected to the showerhead 32 via an upper matcher 33 and supplies predetermined radio frequency electrical power to the showerhead 32. The showerhead 32 thus acts as an upper electrode. It should be noted that the upper matcher 33 has a similar function to the lower matcher 19 described above.

The showerhead 32 has a ceiling electrode plate 36 having therein a number of gas holes 35, a cooling plate 37 that detachably suspends the ceiling electrode plate 36, and a lid member 38 that covers the cooling plate 37. Moreover, a buffer chamber 39 is provided inside the cooling plate 37, and a process gas-introducing pipe 40 is connected to the buffer chamber 39. The showerhead 32 supplies a process gas supplied to the buffer chamber 39 through the process gas-introducing pipe 40 into the reaction chamber 15 via the gas holes 35. In the present embodiment, for example, a CF-based gas is supplied as the process gas into the reaction chamber 15.

In the plasma processing apparatus 10, radio frequency electrical power is supplied to the susceptor 12 and the showerhead 32 to apply radio frequency electrical power to the processing space S so that the process gas supplied from the showerhead 32 is turned into high density plasma to produce ions and radicals, whereby the wafer W is subjected to the etching processing using the ions and the radicals.

Operation of the component parts of the above described plasma processing apparatus 10 is controlled in accordance with a program for the etching processing by a CPU of a control unit (not shown) of the plasma processing apparatus 10.

In the case that a CF-based gas is turned into plasma and the wafer W is subjected to the etching processing by the plasma, CFx radicals are produced in the processing space S. Because the exposed surface of the outer cover ring 25 which is exposed into the processing space S is covered with yttria, the yttria pulls out fluorine in the CFx radicals. For this reason, the radicals that enter the gap between the outer periphery of the wafer W and an inner periphery of the focus ring 23 to reach an outer periphery of the electrostatic chuck 21 under the wafer W includes almost no fluorine, and thus deposit arising from the radicals is carbon-rich deposit. In general, carbon-rich deposit is easily removed by oxygen radicals, but in dry cleaning processing that is carried out in the chamber 11 by the plasma processing apparatus 10, oxygen gas is used as the process gas, and hence the carbon-rich deposit attached to the outer periphery of the electrostatic chuck 21 is easily removed by the dry cleaning processing.

According to the present embodiment, because the exposed surface of the outer cover ring 25 which is exposed into the processing space S in the annular assembly for plasma processing 22 is covered with yttria, deposit does not accumulate in a gap between the outer periphery of the electrostatic chuck 21 and the inner periphery of the focus ring 23 if the dry cleaning is carried out at the time of mass production of wafers W, and thus poor attraction of the wafer W can be prevented.

According to the present embodiment, in the annular assembly for plasma processing 22, the focus ring 23 and the inner cover ring 24 are disposed closer to the wafer W attracted to and held on the electrostatic chuck 21 than the outer cover ring 25. That is, the focus ring 23 and the inner cover ring 24 are interposed between the outer cover ring 25 and the wafer W attracted to and held on the electrostatic chuck 21. As a result, the focus ring 23 and the inner cover ring 24 can act as barriers that prevent yttria contamination resulting from dispersion of yttria in the outer cover ring 25 from spreading to the wafer W, and hence the wafer W can be prevented from being contaminated with yttria.

Moreover, according to the present embodiment, the inner cover ring 24 is disposed such that an upper surface thereof is at a lower level than the upper surface of the focus ring 23 and at a higher level than the upper surface of the outer cover ring 25. That is, the members constituting the annular assembly for plasma processing 22 are arranged in the form of a ladder from the focus ring 23 down to the outer cover ring 25. As a result, the flow of the process gas flowing from above the focus ring 23 to above the outer cover ring 25 in the processing space S and further to the side of the susceptor 12 can be smoothed, and hence the process gas can be smoothly discharged.

Further, according to the present embodiment, the upper surface of the outer cover ring 25 is formed as an inclined surface that is inclined downward to the outer periphery. As a result, the flow of the process gas supplied into the processing space S and discharged downward via the side of the susceptor 12 is not obstructed by the upper surface of the outer cover ring 25, and hence the process gas can be quickly discharged.

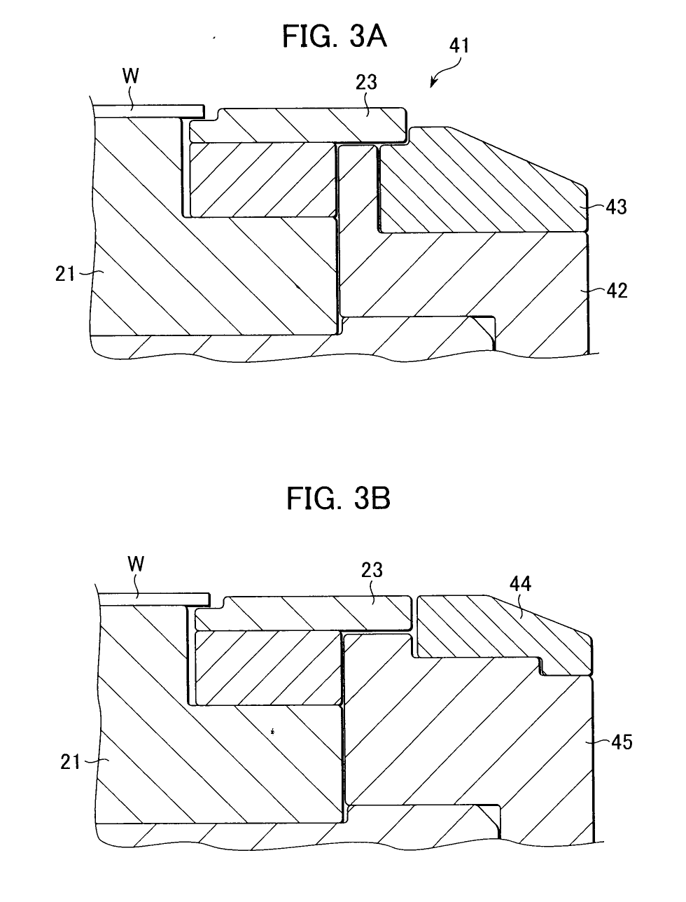

Further, although the annular assembly for plasma processing 22 described above has the inner cover ring 24 that is interposed between the focus ring 23 and the outer cover ring 25, the annular assembly for plasma processing 22 may not be provided with the inner cover ring 24. For example, an annular assembly for plasma processing 41 may be provided with only an outer cover ring 43 mounted on a susceptor cover member 42 in addition to the focus ring 23 as shown in FIG. 3A. As is the case with the outer cover ring 25 described above, the outer cover ring 43 is made of aluminum, and an exposed surface of the outer cover ring 43 is covered with yttria. In this case, as compared with the case that there is provided the annular assembly for plasma processing 22, the exposed surface of the outer cover ring 43 covered with yttria can be made closer to the processing space S, and hence the yttria can effectively pull out fluorine in the CFx radicals described above. Further, as shown in FIG. 3B, an outer cover ring 44 that has a construction similar to the construction of the outer cover rings 25 and 43 described above may be formed in a shape similar to the shape of a conventional cover ring 50. In this case, merely by replacing the cover ring 50 with the outer cover ring 44, fluorine in the CFx radicals can be pulled out, and hence poor attraction of wafers W can be prevented using an inexpensive construction.

Further, in the case of the outer cover rings 25, 43, and 44 described above, when the yttria of the exposed surface pulls out fluorine in the CFx radicals, yttrium chemically reacts with the fluorine. This reaction is an endothermic reaction, and thus the temperatures of the outer cover rings 25, 43, and 44 are preferably high so that the reaction can be promoted. For this reason, in the present embodiment, the outer cover rings 25, 43, and 44 are mounted on the susceptor 12 via susceptor cover members 27, 42, and 45, respectively, which are made of quartz or the like with low heat transferability. This inhibits the outer cover rings 25, 43, and 44 from being cooled by the susceptor 12, and enables the temperatures of the outer cover rings 25, 43, and 44 to be more easily increased by heat input from plasma produced in the processing space S.

Further, although the outer cover rings 25, 43, and 44 described above are made of aluminum, and their exposed surfaces are covered with yttria, they may be formed of yttria alone (bulk).

Although in the above described embodiment, the substrates are semiconductor wafers, the substrate are not limited to them and rather may instead be any of various glass substrates used in LCDs (Liquid Crystal Displays), FPDs (Flat Panel Displays), or the like.

Next, a concrete description will be given of examples of the present invention.

### EXAMPLE 1

First, the above described annular assembly for plasma processing 22 was disposed in the plasma processing apparatus 10.

After that, the etching processing was carried out on oxide films of 65 wafers, and after the wafers W were transferred out, the dry cleaning processing were carried out. Then, the state of deposit attachment to the outer periphery of the electrostatic chuck 21 was visually checked, and the outer periphery of the electrostatic chuck 21 was cleaned by wiping it using a BEMCOT (registered trademark).

### COMPARATIVE EXAMPLE 1

The conventional focus ring 23 and cover ring 50 were disposed in the plasma processing apparatus 10.

After that, as is the case with the above described example 1, the etching processing was carried out on oxide films of 65 wafers, and after the wafers W were transferred out, the dry cleaning processing was carried out. Then, the state of deposit attachment to the outer periphery of the electrostatic chuck 21 was visually checked, and the outer periphery of the electrostatic chuck 21 was cleaned by wiping it using a BEMCOT (registered trademark).

In the comparative example 1, it was visually confirmed that deposit was attached to the outer periphery of the electrostatic chuck 21, and a large amount of deposit was attached to the BEMCOT (registered trademark) after the cleaning using wiping, whereas in the example 1, attachment of deposit to the outer periphery of the electrostatic chuck 21 was not visually confirmed, and further, the amount of deposit attached to the BEMCOT (registered trademark) after cleaning by wiping was obviously smaller than in the comparative example 1. In the example 1, it was also confirmed that the exposed surface of the outer cover ring 25 turned black.

The reason for this was considered to be that in the comparative example 1, CFx radicals produced in the plasma processing reached the outer periphery of the electrostatic chuck 21, caused an attracting reaction on the outer periphery of the electrostatic chuck 21, and turned into CF type deposit to accumulate on the outer periphery of the electrostatic chuck 21, whereas in the example 1, the exposed surface of the outer cover ring 25 turned black, and hence yttria in the exposed surface pulled out fluorine in the CFx radicals produced in the plasma processing, and radicals that reached the outer periphery of the electrostatic chuck 21 included almost no fluorine, and deposit arising from the radicals was carbon-rich deposit, and the deposit was easily removed by the dry cleaning processing and thus did not accumulate on the outer periphery of the electrostatic chuck 21.

Next, the present inventors checked how the etching processing is affected by the presence of the outer cover ring 25 whose surface exposed into the processing space S is covered with yttria.

### EXAMPLE 2

First, as is the case with the example 1, the annular assembly for plasma processing 22 was disposed in the plasma processing apparatus 10.

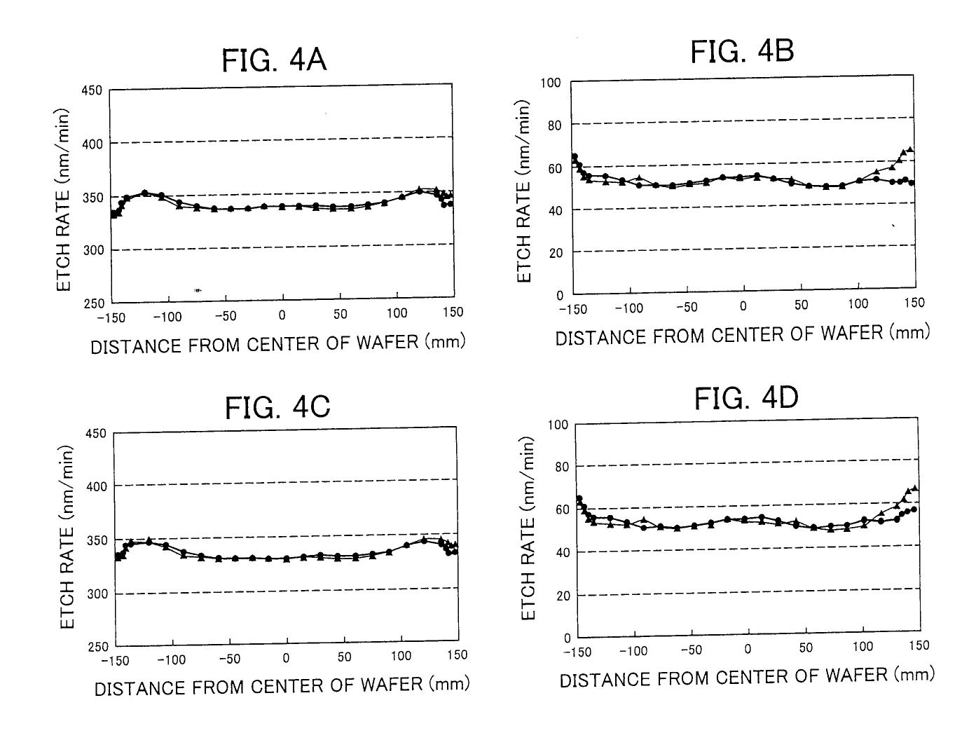

After that, etching processing was carried out on an oxide film on a wafer W, and etch rates in the etching processing were measured. Further, by using another wafer, etching processing was carried out on a photoresist film on the wafer, and etch rates in the etching processing were measured. Then, the results of the etching processing on the oxide film were graphed in FIG. 4A, and the results of the etching processing on the photoresist film were graphed in FIG. 4B.

### COMPARATIVE EXAMPLE 2

As is the case with the comparative example 1, the conventional focus ring 23 and cover ring 50 were disposed in the plasma processing apparatus 10.

After that, etching processing was carried out on an oxide film on a wafer W, and etch rates in the etching processing were measured. Further, by using another wafer, etching processing was carried out on a photoresist film on the wafer, and etch rates in the etching processing were measured. Then, the results of the etching processing on the oxide film were graphed in FIG. 4C, and the results of the etching processing on the photoresist film were graphed in FIG. 4D.

As a result of comparison between FIGS. 4A and 4C and comparison between FIGS. 4B and 4D, it was confirmed that the etch rate does not vary regardless of whether the outer cover ring 25 is present or absent in the etching processing on an oxide film and the etching processing on a photoresist film. It was thus found that the presence of the outer cover ring 25 hardly affects the etching processing.

What is claimed is:

1. An annular assembly for plasma processing, comprising:
a focus ring that is mounted on a mounting stage and disposed such as to surround an outer periphery of a substrate subjected to plasma processing; and
an outer annular member that is disposed such as to surround an outer periphery of said focus ring,
wherein said outer annular member comprises an exposed surface that is exposed into a plasma producing space in which plasma is produced, and said exposed surface is covered with yttria.

2. An annular assembly for plasma processing as claimed in claim 1, comprising an inner annular member that is disposed such as to surround the outer periphery of said focus ring, and is closer to said focus ring than said outer annular member.

3. An annular assembly for plasma processing as claimed in claim 2, wherein said inner annular member comprises quartz.

4. An annular assembly for plasma processing as claimed in claim 2, wherein said inner annular member is disposed such that an upper surface thereof is at a lower level than an upper surface of said focus ring and at a higher level than an upper surface of said outer annular member.

5. An annular assembly for plasma processing as claimed in claim 1, wherein said outer annular member comprises an upper surface thereof formed as an inclined surface that is inclined downward toward an outer periphery.

6. A plasma processing apparatus comprising:
a processing chamber in which a substrate is subjected to plasma processing;
a mounting stage that is disposed in said processing chamber, and on which the substrate is mounted; and
an annular assembly for plasma processing which is disposed such as to surround an outer periphery of the substrate mounted on said mounting stage,
wherein said annular assembly for plasma processing comprises a focus ring that is disposed such as to surround the outer periphery of the substrate, and an outer annular member that is disposed such as to surround an outer periphery of said focus ring, and
said outer annular member comprises an exposed surface that is exposed into a plasma producing space in which plasma is produced, and said exposed surface is covered with yttria.

7. An outer annular member that is disposed such as to surround an periphery of a focus ring that is disposed such as to surround an outer periphery of a substrate mounted on a mounting stage and subjected to plasma processing, comprising:
an exposed surface that is exposed into a plasma producing space in which plasma is produced, and said exposed surface is covered with yttria.
